(19) United States
(12) Patent Application Publication
(10) Pub. No.: US 2008/0147387 A1
(43) Pub. Date: Jun. 19, 2008

(54) AUDIO SIGNAL PROCESSING DEVICE AND NOISE SUPPRESSION PROCESSING METHOD IN AUTOMATIC GAIN CONTROL DEVICE

(75) Inventors: Mitsuyoshi Matsubara, Fukuoka (JP); Kazuhiro Nomoto, Fukuoka (JP)

Correspondence Address: KATTEN MUCHIN ROSENMAN LLP, 575 MADISON AVENUE, NEW YORK, NY, 10022-2585, US

(73) Assignee: FUJITSU LIMITED, Kawasaki-shi (JP)

(21) Appl. No.: 11/877,787

(22) Filed: Oct. 24, 2007

(30) Foreign Application Priority Data
Dec. 13, 2006 (JP) JP2006-335326

(51) Int. Cl. H04B 15/00; H03G 3/20

(52) U.S. Cl. 704/225; 381/94.1

(57) ABSTRACT

An audio signal processing device includes a gain control portion (11, 12) that controls a gain of an input audio signal (S1), a noise suppression quantity calculating portion (13) that calculates noise suppression quantity (SL) with respect to the audio signal, a correcting portion (14) that corrects the noise suppression quantity (SL) based on a gain (GL) calculated by the gain control portion, and a noise suppressing portion (15) that suppresses a noise component included in the audio signal based on a corrected noise suppression quantity (SLH).

### BACKGROUND OF THE INVENTION

1. Field of the Invention

The present invention relates to a method for a noise suppression process in an automatic gain control device that adjusts a gain of an audio signal so that a level of the audio signal becomes substantially constant, and an audio signal processing device. In particular, the present invention relates to a method and a device for adjusting a level of an audio signal to an optimal level in the case where the audio signal includes background noise and for preventing generation of fluctuations of noise components accompanying the level adjustment of the audio signal.

2. Description of the Prior Art

Along with the recent growing scale and functions of communication networks, videoconference systems and mobile phones have become widespread and their functions have been improved. In audio communication systems such as videoconference systems and mobile phones, an audio level of a microphone input varies in accordance with a distance between a microphone and a speaker, a voice level of the speaker or the like. As a result, an audio level of a received signal on a receiving side may vary, which causes difficulty in hearing. In order to solve this problem, an automatic gain control device (an automatic gain adjustment device) is used for controlling so that the audio signal becomes an optimal constant level.

A general automatic gain control device performs audio detection first about whether or not the input signal includes an audio signal. If it is decided that the audio signal is included in a certain interval, an average value of audio power (an average audio power) in the interval is calculated based on an instantaneous power of the input signal. This average audio power is compared with an audio level to be a target (a target audio power), and a gain for the input signal is calculated. Then, the input signal is amplified so that the gain is obtained (see Japanese unexamined patent publication No. 1-286633).

However, this method has a following problem. For example, if the mobile phone is used in an outdoor place, a microphone may receive not only the voice but also background noise such as ambient noise. If the automatic gain control (AGC) is performed in such a case, the background noise is also amplified by the same gain together with the voice.

Here, an example of the case where a level fluctuation of the voice VC is large though a level of the background noise HZ is substantially constant like an input signal (audio signal) S1 shown in FIG. 4A will be described. In this case, if the control is tried so that a level of the voice VC becomes constant, a level of the background noise HZ will increase together with the voice VC like the output signal S1 shown in FIG. 4B in the interval KK2 in which a level of the voice VC as the input signal is small. As a result, a fluctuation in a background noise component is generated between the intervals KK1 and KK3 in which a level of the voice VC as the input signal is large and the interval KK2 in which the level of the voice VC is small, which is not good for audibility.

In order to solve this problem, it is proposed to remove the noise component before the automatic gain control is performed (see Japanese unexamined patent publication No. 10-98346). However, it is difficult to remove the background noise HZ completely by the method disclosed in Japanese unexamined patent publication No. 10-98346. Therefore, there is still generated a fluctuation in the residual noise component like the output signal S12 shown in FIG. 4C.

As described above, since the background noise HZ cannot be removed completely by the conventional method, a noise component remains in the input signal in any case, which causes a fluctuation in the noise component when the automatic gain control is performed.

### SUMMARY OF THE INVENTION

An object of the present invention is to provide a device and a method that is capable of adjustment so that a level of an audio signal becomes constant by automatic gain control even if a level of an input audio signal varies, and that can prevent generation of fluctuations of a noise component.

A device according to one aspect of the present invention includes a gain control portion that controls a gain of an input audio signal, a noise suppression quantity calculating portion that calculates noise suppression quantity with respect to the audio signal, a correcting portion that corrects the noise suppression quantity based on a gain calculated by the gain control portion, and a noise suppressing portion that suppresses a noise component included in the audio signal based on a corrected noise suppression quantity.

Since the correcting portion corrects the noise suppression quantity in accordance with a gain, the noise suppression quantity decreases in an interval having a small gain and increases in an interval having a large gain. As a result, the noise component becomes substantially constant so that fluctuations are suppressed.

Preferably, the correcting portion may adjust the noise suppression quantity in proportion to the gain calculated by the gain control portion.

According to the present invention, if a level of an input audio signal varies, the automatic gain control is performed so that a level of the audio signal can be adjusted to be constant and that fluctuations of the noise component are hardly generated.

### BRIEF DESCRIPTION OF THE DRAWINGS

FIG. 1 is a block diagram showing an example of a structure of an audio signal processing device according to the present invention.

FIG. 2 is a diagram showing examples of a relationship between a gain and a correction quantity.

FIG. 3 is a diagram showing examples of a relationship between an S/N ratio of an audio signal and a noise suppression quantity.

FIGS. 4A-4D are diagrams showing examples of states of the audio signal and audio signals after gain control, a noise suppression process and the like are performed.

FIGS. 5A-5C are diagrams showing examples of the gain, the noise suppression quantity and the correction quantity with respect to the audio signal shown in FIG. 4.

### DESCRIPTION OF THE PREFERRED EMBODIMENTS

The invention will now be described in detail with reference to the attached drawings.

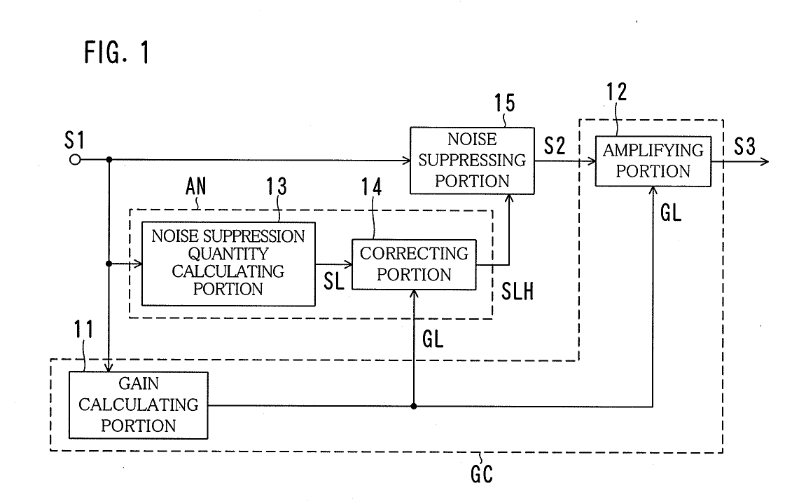

As shown in FIG. 1, the audio signal processing device 3 includes a gain calculating portion 11, an amplifying portion 12, a noise suppression quantity calculating portion 13, a correcting portion 14 and a noise suppressing portion 15.

The gain calculating portion 11 calculates a gain GL for the entered audio signal S1. A method of calculating the gain GL can be one of various known methods. For example, the gain GL can be calculated from an average value of voice power during the voice interval of the audio signal S1 and a target level. Note that the “audio signal” in this description means a signal concerning voice regardless of a form of the signal and includes intrinsic “voice” that is necessary for transmission of information and noise components such as “background noise”.

The amplifying portion 12 amplifies an audio signal S2 delivered from the noise suppressing portion 15 in accordance with the gain GL calculated by the gain calculating portion 11. As a result, the amplifying portion 12 delivers an audio signal S3 having a substantially constant level. Note that the gain GL can be “1” or less, so the term “amplification” includes “attenuation” in this description.

The noise suppression quantity calculating portion 13 calculates noise suppression quantity SL with respect to the audio signal S1. A method of calculating the noise suppression quantity SL can be one of various known methods. For example, the audio signal S1 in a time domain is converted to one in a frequency domain, and a spectrum analysis is performed so as to extract noise components for obtaining its estimated noise (an average in a long period). This result is compared with the original audio signal S1 so as to determine a noise suppression quantity SL in accordance with the S/N ratio (SNR). In general, if the S/N ratio is small (i.e., if there are many noise components), the noise suppression quantity SL is increased so as to improve clarity. If the S/N ratio is large, the noise suppression quantity SL is decreased so as to enhance fidelity of voice.

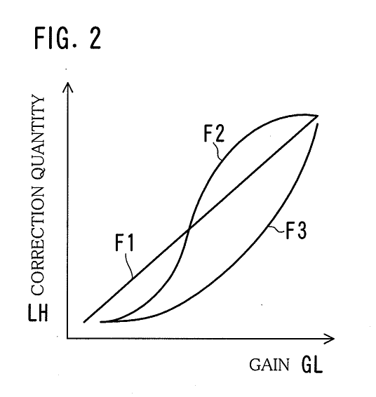

The correcting portion 14 corrects the noise suppression quantity SL based on the gain GL calculated by the gain calculating portion 11. In other words, the noise suppression quantity SL is increased or decreased in accordance with the gain GL. For example, the correction is performed so that the correction quantity LH, i.e., the noise suppression quantity SL is increased or decreased in proportion to the gain GL like a function F1 shown in FIG. 2. Alternatively, the correction is performed so that it is increased or decreased in a manner of gamma function with respect to the gain GL like a function F2 shown in FIG. 2. Alternatively, the correction is performed so that it is increased or decreased in a manner of log function with respect to the gain GL like a function F3 shown in FIG. 2.

Note that the correction quantity LH and the corrected noise suppression quantity SLH can be expressed by the following general equations.

LH=f(GL)

SLH=f(GL, SL)

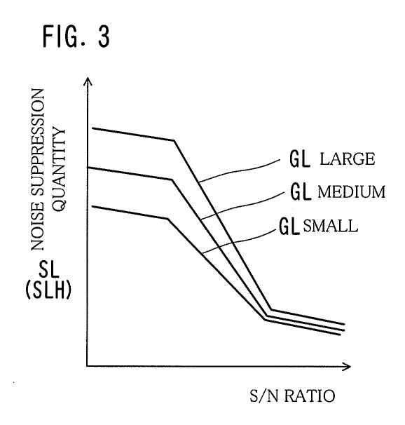

Furthermore, concerning a relationship between the S/N ratio of the audio signal S1 and the noise suppression quantity SL, as shown in FIG. 3 for example, if the S/N ratio is small, i.e., if there are many noise components, the noise suppression quantity SL is large. If the S/N ratio is large, i.e., if there are little noise components, the noise suppression quantity SL is small. Then, if the gain GL is small, i.e., if a voice component (voice power) is large, the noise suppression quantity SL is decreased in the interval having a small S/N ratio so that deterioration of sound quality is minimized. If the gain GL is large, i.e., if the voice component is small, the noise suppression quantity SL is increased in the interval having a small S/N ratio so that noises are removed while clarity of the sound quality is increased.

The noise suppressing portion 15 suppresses the noise component included in the audio signal S1 in accordance with the corrected noise suppression quantity SLH. As a result, the noise suppressing portion 15 delivers the audio signal S2 in which the noise component of the audio signal S1 is suppressed.

Note that the audio signal processing device 3 can be made up of a DSP or a CPU that executes an appropriate program, or a hardware circuit using circuit elements, or a combination thereof. In addition, the audio signal processing device 3 can perform a digital process, an analog process or a combination process of them.

The gain calculating portion 11 and the amplifying portion 12 constitute a gain control portion GC. In other words, the gain calculating portion 11 and the amplifying portion 12 may constitute a process or a circuit as one gain control portion GC. In addition, the noise suppression quantity calculating portion 13 and the correcting portion 14 constitute an automatic noise suppression quantity calculating portion AN. In other words, the noise suppression quantity calculating portion 13 and the correcting portion 14 may constitute a process or a circuit as one automatic noise suppression quantity calculating portion AN. In addition, it is possible to constitute the automatic noise suppression quantity calculating portion AN by including also the noise suppressing portion 15. In addition, it is possible to make the entire audio signal processing device 3 as a single process or circuit.

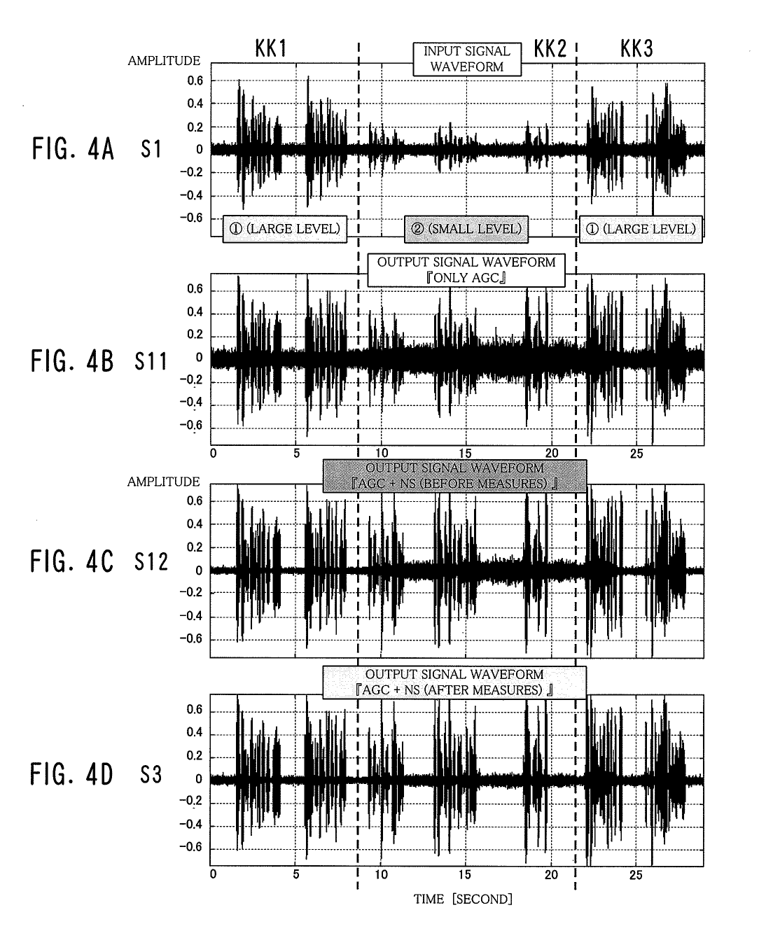

Next, the case where the audio signal S1 shown in FIG. 4A is supplied to the audio signal processing device 3 will be described in a specific manner.

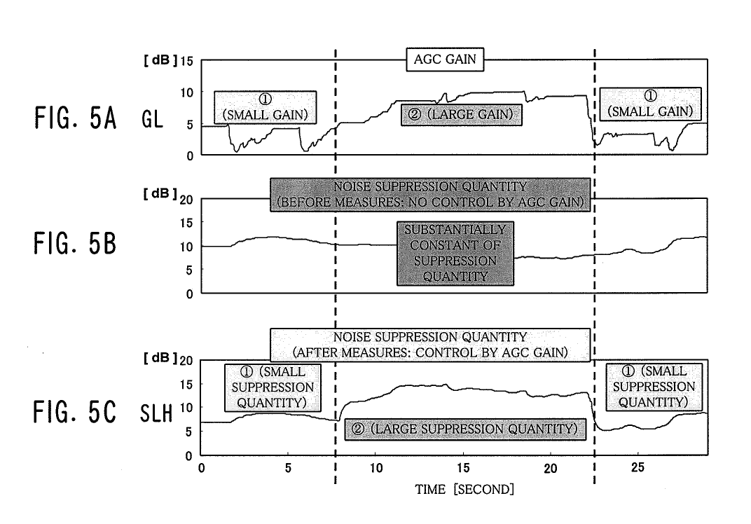

The audio signal S1 shown in FIG. 4A has a substantially constant level of noises and an audio level that varies largely. In this case, the gain calculating portion 11 calculates as shown in FIG. 5A, so that the gain GL decreases in the intervals KK1 and KK3 having a large audio level while the gain GL increases in the interval KK2 having a small audio level.

Since the level of noises is substantially constant, the noise suppression quantity SL becomes substantially constant as shown in FIG. 5B if the conventional control is performed. In this case, as mentioned above in the description of background arts, fluctuations of the noise component are generated in the audio signal as shown in FIGS. 4B and 4C.

As to the audio signal processing device 3 according to the present embodiment, the correcting portion 14 corrects the noise suppression quantity SL in accordance with the gain GL. As a result, as shown in FIG. 5C, the corrected noise suppression quantity SLH decreases in the intervals KK1 and KK3 having a small gain GL and increases in the interval KK2 having a large gain GL.

As a result, as shown in FIG. 4D, the audio level of the audio signal S3 becomes substantially constant. In addition, the noise component is removed and the level thereof becomes substantially constant, so that fluctuations of the noise component are substantially eliminated.

Thus, a listener who listens to the voice with a speaker or an earphone can hear the voice at a constant level. In addition, a level of the noise component is substantially constant without fluctuations, and the noise component is reduced to a small level. Therefore, difficulty in hearing is eliminated, so that the voice becomes listenable.

The audio signal processing device 3 of the embodiment described above can be incorporated into a receiving side or a transmitting side of a mobile phone, or a voice output circuit of a videoconference system, for example.

Although the noise suppressing portion 15 is provided to a part before the amplifying portion 12 in the embodiment described above, it is possible to provide the noise suppressing portion 15 to a part after the amplifying portion 12. Furthermore, the structure, the shape, the size, the number, the circuit of the entire or each part of the noise suppression quantity calculating portion 13, the correcting portion 14, the noise suppressing portion 15, the gain control portion GC, the automatic noise suppression quantity calculating portion AN or the audio signal processing device 3, the process contents, the process order, the size of the interval, the values of various parameters or operational equations and the like can be modified if necessary in accordance with the spirit of the present invention.

While example embodiments of the present invention have been shown and described, it will be understood that the present invention is not limited thereto, and that various changes and modifications may be made by those skilled in the art without departing from the scope of the invention as set forth in the appended claims and their equivalents.

What is claimed is:

1. An audio signal processing device comprising:
a gain control portion that controls a gain of an input audio signal;
a noise suppression quantity calculating portion that calculates noise suppression quantity with respect to the audio signal;
a correcting portion that corrects the noise suppression quantity based on a gain calculated by the gain control portion; and
a noise suppressing portion that suppresses a noise component included in the audio signal based on a corrected noise suppression quantity.

2. The audio signal processing device according to claim 1, wherein the correcting portion adjusts the noise suppression quantity in proportion to the gain calculated by the gain control portion.

3. An audio signal processing device comprising:
a gain calculating portion that calculates a gain with respect to an input audio signal;
an amplifying portion that amplifies the audio signal in accordance with the gain;
a noise suppression quantity calculating portion that calculates noise suppression quantity with respect to the audio signal so as to increase or decrease the noise suppression quantity in accordance with the gain; and
a noise suppressing portion that suppresses a noise component included in the audio signal in accordance with the noise suppression quantity.

4. A noise suppression processing method in an automatic gain control device that controls a gain of an audio signal so that a level of the audio signal becomes substantially constant, the method comprising the steps of:
correcting noise suppression quantity with respect to the audio signal so that the noise suppression quantity increases or decreases in accordance with a gain with respect to the audio signal; and
suppressing a noise component included in the audio signal by using a corrected noise suppression quantity.
